(19) United States
(12) Patent Application Publication
(10) Pub. No.: US 2025/0173857 A1
(43) Pub. Date: May 29, 2025

(54) METHOD OF DETECTING DEFECTIVE SEMICONDUCTOR PACKAGE

(71) Applicant: SAMSUNG ELECTRONICS CO., LTD., SUWON-SI (KR)

(72) Inventors: Sunghyun KIM, Suwon-si (KR); Ikjong PARK, Suwon-si (KR); Dongsoo LEE, Suwon-si (KR); Choonsik KIM, Suwon-si (KR); Changhyun LEE, Suwon-si (KR)

(21) Appl. No.: 18/926,508

(22) Filed: Oct. 25, 2024

(30) Foreign Application Priority Data
Nov. 23, 2023 (KR) 10-2023-0164493

(51) Int. Cl. G06T 7/00; G06T 7/73; H01L 21/66

(52) U.S. Cl. CPC G06T 7/001; G06T 7/74; H01L 22/12; G06T 2207/20084; G06T 2207/30141; G06T 2207/30148; G06T 2207/30152; G06T 2207/30204

(57) ABSTRACT

A method of detecting a defective semiconductor package includes obtaining a target image of a backside surface of a package substrate that includes a pair of window patterns and connection terminal arrays extending in a first direction. A shift value of the pair of window patterns illustrated in the target image is measured, and the shift value is compared with a reference value to determine whether the package substrate is defective or is not defective. The measuring of the shift value of the pair of window patterns includes obtaining a first center position value between a pair of adjacent connection terminal arrays that are farthest away from each other among pairs of adjacent connection terminal arrays. A second center position value is obtained between the pair of window patterns. A difference between the first center position value and the second center position value is defined as the shift value.

### CROSS-REFERENCE TO RELATED APPLICATION

This application claims priority under 35 U.S.C. § 119 to Korean Patent Application No. 10-2023-0164493, filed on Nov. 23, 2023 in the Korean Intellectual Property Office, the disclosure of which is incorporated by reference in its entirety herein.

### 1. TECHNICAL FIELD

The present inventive concept relates to a method of detecting a defective semiconductor package, and more particularly, to a method of detecting a defective semiconductor package, which determines whether a package substrate of a semiconductor package is defective or not.

### 2. DISCUSSION OF RELATED ART

Electronic devices have become increasingly miniaturized and lightweight along with the advancement of the electronics industry. Semiconductor packages are also being miniaturized and made lightweight for application to electronic devices. The semiconductor packages should provide high performance, large capacity, and high reliability. However, the power consumption of semiconductor packages are increasing as the semiconductor packages provide an increasingly high performance and large capacity. Therefore, research is being conducted concerning structures of semiconductor packages which respond to the size and performance of semiconductor packages and stably supply power to a semiconductor package and a method of determining whether a semiconductor package is defective.

### SUMMARY

Embodiments of the present inventive concept provide a method of detecting a defective semiconductor package, in which reliability is increased.

However, the objects of embodiments of the present inventive concept are not limited to the aforesaid.

According to an embodiment of the present inventive concept, a method of detecting a defective semiconductor package includes obtaining a target image of a backside surface of a package substrate that includes a pair of window patterns and a plurality of connection terminal arrays extending in a first direction. A shift value is measured of the pair of window patterns illustrated in the target image. The shift value are compared with a reference value to determine whether the package substrate is defective or is not defective. The measuring of the shift value of the pair of window patterns comprises obtaining a first center position value between a pair of adjacent connection terminal arrays that are farthest away from each other among pairs of adjacent connection terminal arrays of the plurality of connection terminal arrays. A second center position value is obtained between the pair of window patterns. A difference between the first center position value and the second center position value is defined as the shift value.

According to an embodiment of the present inventive concept, a method of detecting a defective semiconductor package includes obtaining a target image of a backside surface of a package substrate that includes a pair of window patterns and a plurality of connection terminal arrays extending in a first direction. A position value of each of the plurality of connection terminal arrays is measured in a second direction perpendicular to the first direction in the target image. A first center connection terminal array and a second center connection terminal array are defined that comprise a pair of adjacent connection terminal arrays that are farthest away from each other among pairs of adjacent connection terminal arrays of the plurality of connection terminal arrays. A first center position value is obtained between a position value of the first center connection terminal array in the second direction and a position value of the second center connection terminal array in the second direction. Position values of each of the pair of window patterns are measured in the second direction. A second center position value is obtained between the position values of the pair of window patterns in the second direction. A difference between the first center position value and the second center position value is defined as a shift value. The shift value is compared with a reference value to determine whether the package substrate is defective or is not defective.

According to an embodiment of the present inventive concept, a method of detecting a defective semiconductor package includes obtaining an image of a backside surface of a printed circuit board (PCB) that includes a pair of window patterns and a plurality of solder ball arrays extending in an X-axis direction. A target image is extracted from the image. A position value of each of the plurality of solder ball arrays in a Y-axis direction is measured in the target image. A first solder ball array and a second solder ball array are defined that comprise a pair of adjacent solder ball arrays that are farthest away from each other in the Y-axis direction among pairs of adjacent solder ball arrays of the plurality of solder ball arrays. A first center position value is obtained that is an average of a position value of the first solder ball array in the Y-axis direction and a position value of the second solder ball array in the Y-axis direction. A position value of each of the pair of window patterns in the Y-axis direction is measured. A second center position value is obtained that is an average of the position values of the pair of window patterns in the Y-axis direction. A difference between the first center position value and the second center position value is defined as a shift value. The shift value is compared with a reference value to determine whether the PCB is defective or is not defective.

### BRIEF DESCRIPTION OF THE DRAWINGS

Embodiments of the present inventive concept will be more clearly understood from the following detailed description taken in conjunction with the accompanying drawings in which:

FIG. 1 is a cross-sectional view of a semiconductor package on which a method of detecting a defective semiconductor package is to be performed, according to an embodiment of the present inventive concept;

FIG. 2 is a flowchart of a method of detecting a defective semiconductor package, according to an embodiment of the present inventive concept;

FIGS. 3 to 9 are diagrams sequentially illustrating processes of a method of detecting a defective semiconductor package, according to embodiments of the present inventive concept;

FIG. 10 is a flowchart of a method of detecting a defective semiconductor package, according to an embodiment and is a flowchart including a method of detecting a defective window pattern illustrated in FIG. 2 according to an embodiment of the present inventive concept; and

FIGS. 11 and 12 are configuration diagrams illustrating a defective semiconductor package detection system for implementing a method of detecting a defective semiconductor package, according to an embodiment of the present inventive concept.

### DETAILED DESCRIPTION OF EMBODIMENTS

Hereinafter, embodiments of the present inventive concept will be described in detail with reference to the accompanying drawings. However, embodiments of the present inventive concept are not limited to the described embodiments and may be embodied in various other forms.

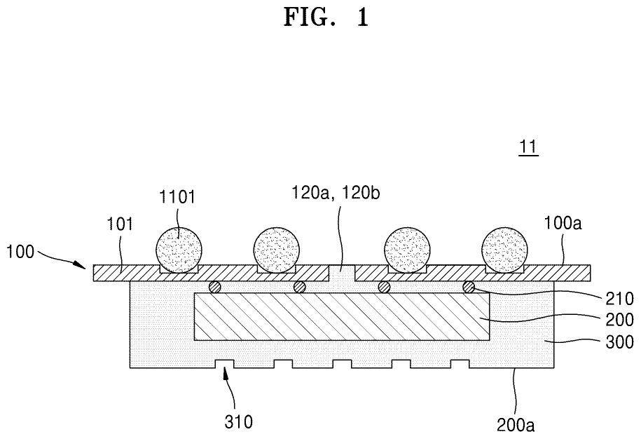

FIG. 1 is a cross-sectional view of a semiconductor package 11 on which a method of detecting a defective semiconductor package is to be performed, according to an embodiment.

Referring to FIG. 1, in an embodiment the semiconductor package 11 may include a package substrate 100, a semiconductor chip 200 mounted on the package substrate 100, an encapsulation layer 300 on the package substrate 100 and burying the semiconductor chip 200, and a connection terminal 1101 attached on a backside surface of the package substrate 100. In an embodiment, the semiconductor chip 200 may be mounted on the package substrate 100 through a chip connection terminal 210 by using a flip chip scheme. However, embodiments of the present inventive concept are not necessarily limited thereto and various different schemes for mounting the semiconductor chip 200 on the package substrate 100 may be utilized.

The package substrate 100 may be, for example, a printed circuit board (PCB). In an embodiment, the package substrate 100 may include a substrate base 101 including at least one material selected from among phenol resin, epoxy resin, and polyimide.

The semiconductor chip 200 may be mounted on the package substrate 100. The semiconductor chip 200 may include an integrated circuit. In an embodiment, the integrated circuit may be any integrated circuit including a memory circuit, a logic circuit, or a combination thereof. The memory circuit may include, for example, a dynamic random access memory (DRAM) circuit, a static random access memory (SRAM) circuit, a flash memory circuit, an electrically erasable programmable read-only memory (EEPROM) circuit, a phase-change random access memory (PRAM) circuit, a magnetoresistive random access memory (MRAM) circuit, a resistive random access memory (RRAM) circuit, or a combination thereof. The logic circuit may include, for example, a central processing unit (CPU) circuit, a graphics processing unit (GPU) circuit, a controller circuit, an application specific integrated circuit (ASIC) circuit, an application processor (AP) circuit, or a combination thereof. However, embodiments of the present inventive concept are not necessarily limited thereto.

The encapsulation layer 300 may seal the semiconductor chip 200, on the package substrate 100. For example, as shown in FIG. 1, the encapsulation layer 300 may directly contact the package substrate 100 and may surround the semiconductor chip 200. In an embodiment, the encapsulation layer 300 may include epoxy-group molding resin or polyimide-group molding resin. For example, the encapsulation layer 300 may include epoxy molding compound (EMC).

Window patterns 120a and 120b exposed through a vent hole may be formed in a backside surface 100a of the package substrate 100. The vent hole may provide a path through which air and the encapsulation layer 300 configured to seal the semiconductor chip 200 of the semiconductor package 11 are discharged. In an embodiment, the encapsulation layer 300 may fill the vent hole and an inner portion of the semiconductor package 11 with the semiconductor chip 200 mounted thereon, and thus, a portion of the encapsulant of the encapsulation layer 300 exposed at the vent hole may form the window patterns 120a and 120b.

A package mark 310 may be formed on a front-side surface 300a of the encapsulation layer 300. In an embodiment, the package mark 310 may be formed by etching the encapsulation layer 300. In an embodiment, the package mark 310 may include information such as a product name or a serial number of the semiconductor package 11.

In an embodiment, a plurality of connection terminals 1101 may be attached on (e.g., disposed directly thereon) the backside surface 100a of the package substrate 100. Each of the plurality of connection terminals 1101 may be, for example, a solder ball. The connection terminal 1101 is described below in detail.

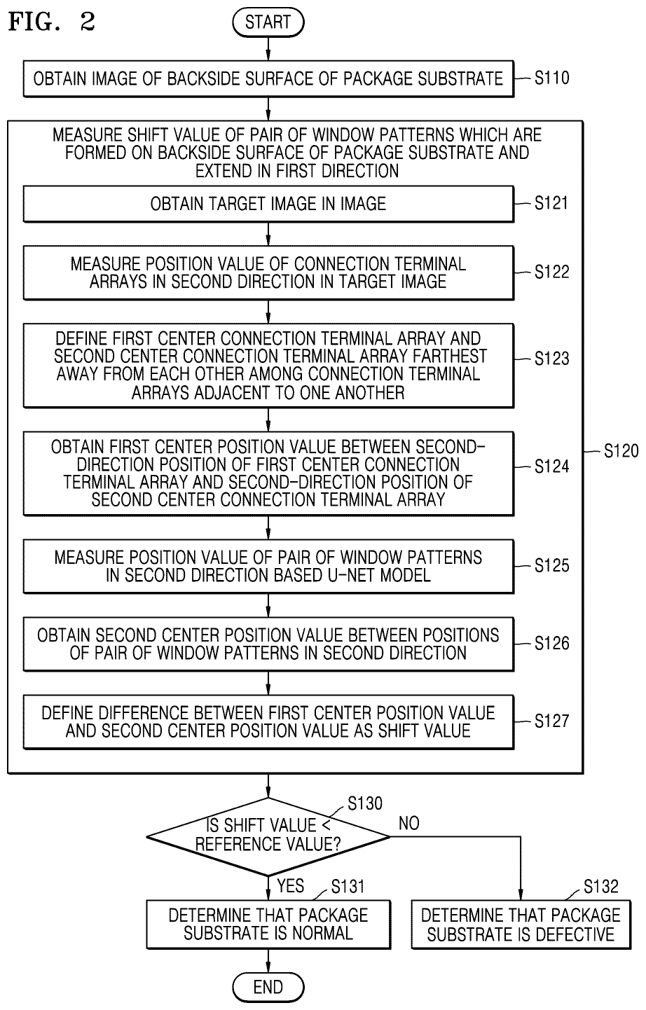

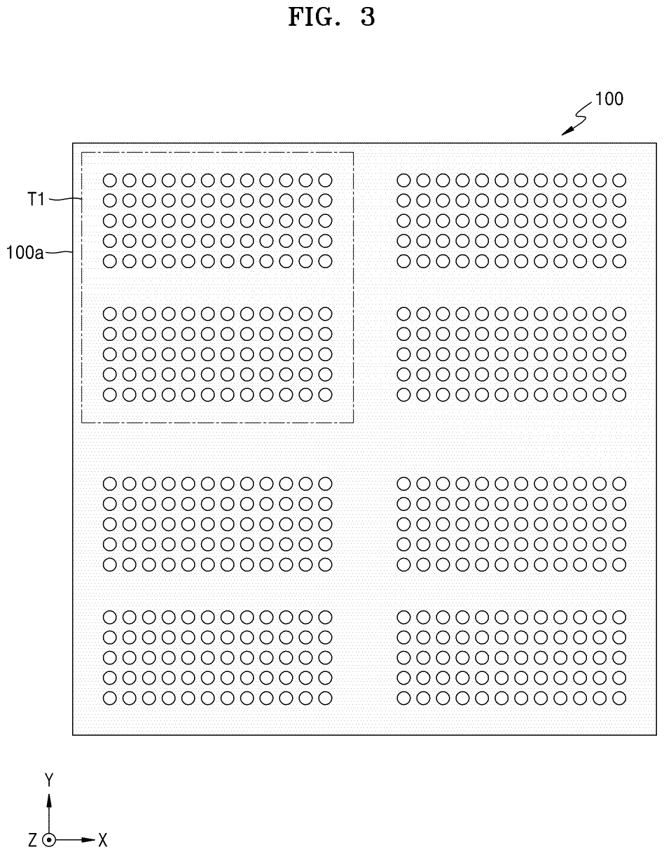

FIG. 2 is a flowchart of a method of detecting a defective semiconductor package, according to an embodiment, and FIGS. 3 to 9 are diagrams illustrating sequential processes of a method of detecting a defective semiconductor package, according to embodiments of the present inventive concept. Hereinafter, a method of detecting a defective semiconductor package is described with reference to FIGS. 3 to 9 in conjunction with FIG. 2.

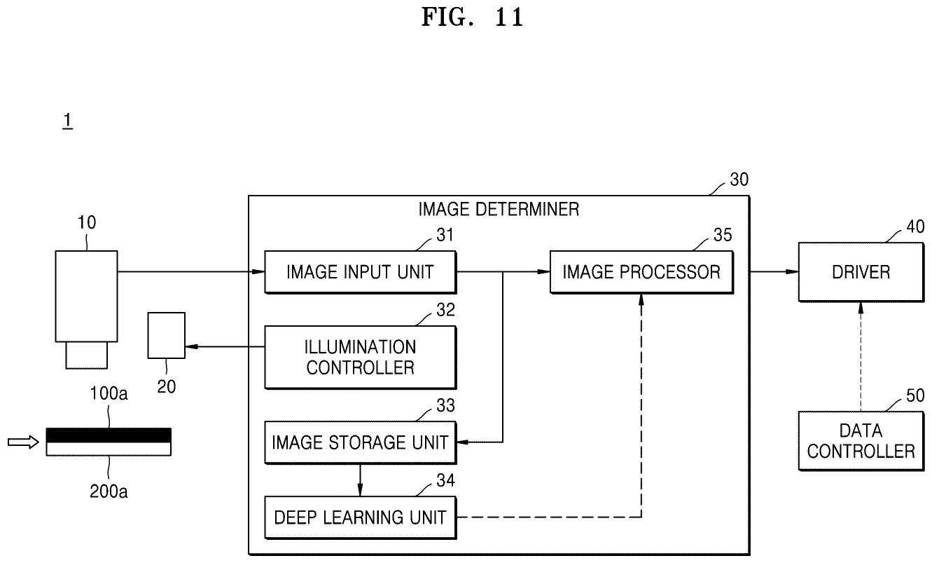

Referring to FIGS. 3 to 9 in conjunction with FIG. 2, a method of detecting a defective semiconductor package, according to an embodiment, may include operation S110 of obtaining an image of a backside surface 100a of a package substrate 100. The image may include an image capturing the backside surface 100a of the package substrate 100. The image of the backside surface 100a of the package substrate 100 may be obtained by a camera 10 (see FIG. 11). In an embodiment, the camera 10 (see FIG. 11) configured to capture the image of the backside surface 100a of the package substrate 100 may be the same as a camera 10 (see FIG. 11) configured to photograph a front-side surface 300a of an encapsulation layer 300 so as to detect whether a package mark 310 (see FIG. 1) is defective or is not defective (e.g., normal).

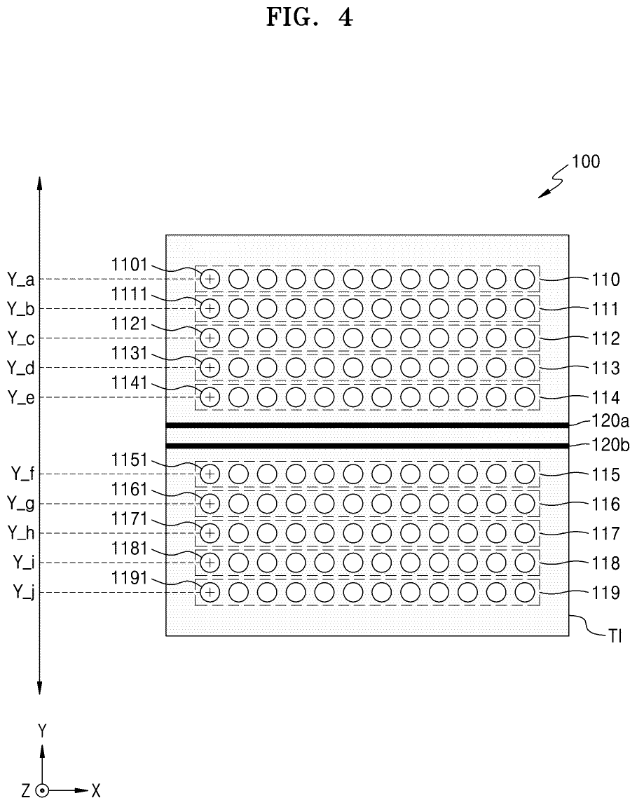

Referring to FIGS. 3 and 4 in conjunction with FIG. 2, the method of detecting a defective semiconductor package, according to an embodiment, may include operation S120 of measuring shift values of a pair of window patterns 120a and 120b that are formed on the backside surface 100a of the package substrate 100 and which extend in a first direction (e.g., an X direction). In an embodiment, operation S210 of measuring the shift values of the pair of window patterns 120a and 120b may include operation S121 of obtaining a target image TI from a captured image of the backside surface 100a of the package substrate 100 by extracting (e.g., dividing) a target image TI from the captured image.

Here, two directions substantially parallel to a lower surface of the package substrate 100 may respectively define a first direction (e.g., an X direction) and a second direction (e.g., a Y direction), and a direction substantially perpendicular to the backside surface 100a of the package substrate 100 may define a vertical direction (e.g., a Z direction). In an embodiment, the first direction (the X direction) and the second direction (the Y direction) may be substantially perpendicular to each other. However, embodiments of the present inventive concept are not necessarily limited thereto and the first and second directions X, Y may cross each other at various different angles. The term ‘vertical direction’ used below may denote a direction substantially parallel to a third direction (e.g., a Z direction). Also, the term ‘horizontal direction’ may denote the first direction (e.g., the X direction), the second direction (e.g., the Y direction), or a direction which is perpendicular to the third direction (e.g., the Z direction) and is oblique to the first direction (e.g., the X direction) and the second direction (e.g., the Y direction). Hereinafter, unless separately described in all drawings, the definition of a direction may be the same herein.

The target image TI may be an image where the shift values of the window patterns 120a and 120b are to be measured. In an embodiment, the package substrate 100 illustrated in the target image TI may be the package substrate 100 of one semiconductor package 11 (see FIG. 1). The package substrate 100 illustrated in the target image TI may be, for example, a PCB. In an embodiment, the package substrate 100 may include a substrate base including at least one material selected from among phenol resin, epoxy resin, and polyimide. Also, the package substrate 100 may include a substrate lower pad disposed on a lower surface of the substrate base and a connection terminal array 110 attached on the substrate lower pad. In an embodiment, an internal wiring pattern electrically connected to the substrate lower pad may be formed in the substrate base. The internal wiring pattern may include a line pattern extending in the horizontal direction (e.g., the X direction or the Y direction) in the package substrate 100 and a via pattern extending in the vertical direction (e.g., the Z direction) in the package substrate 100.

According to an embodiment, a plurality of connection terminal arrays, such as first to tenth connection terminal arrays 110 to 119, may be disposed on the backside surface 100a of the package substrate 100. In an embodiment, each of the plurality of connection terminal arrays 110 to 119 may include a plurality of connection terminals 1101 to 1191 which are arranged to be spaced apart from one another in the first direction (e.g., the X direction). For example, in an embodiment the first connection terminal array 110, the second connection terminal array 111, the third connection terminal array 112, the fourth connection terminal array 113, and the fifth connection terminal array 114 may be arranged in a first region in the second direction (e.g., the Y direction). Also, the sixth connection terminal array 115, the seventh connection terminal array 116, the eighth connection terminal array 117, the ninth connection terminal array 118, and the tenth connection terminal array 119 may be arranged in a second region opposite to the first region (e.g., in the Y direction) where the first to fifth connection terminal arrays 110 to 114 are arranged. The pair of window patterns 120a and 120b may be disposed between the first and second regions (e.g., in the Y direction). The plurality of connection terminal arrays 110 to 119 may be arranged to be spaced apart from one another in the second direction (e.g., the Y direction).

The number of connection terminal arrays 110 to 119 illustrated in FIG. 4 and the number of connection terminals 1101 to 1191 configuring each of the plurality of connection terminal arrays 110 to 119 may be merely an embodiment. However, embodiments of the present inventive concept are not necessarily limited thereto. In an embodiment, the length of each of the pair of window patterns 120a and 120b in the first direction (e.g., the X direction) may be greater than the length of each of the connection terminal arrays 110 to 119 in the first direction (e.g., in the X direction).

According to an embodiment, the plurality of connection terminals 1101 to 1191 may include, for example, a conductive material including tin (Sn), lead (Pb), silver (Ag), copper (Cu), or a combination thereof. The connection terminals 1101 to 1191 may each include, for example, a solder ball. In an embodiment, the connection terminals 1101 to 1191 may connect (e.g., electrically connect) a semiconductor package to a circuit board, another semiconductor package, an interposer, or a combination thereof.

A connection terminal disposed outermost (e.g., in the −X direction) among the connection terminals configuring the first connection terminal array 110 may be defined as the first connection terminal 1101. Likewise, connection terminals disposed outermost (e.g., in the—X direction) among connection terminals respectively configuring the second connection terminal array 111, the third connection terminal array 112, the fourth connection terminal array 113, the fifth connection terminal array 114, the sixth connection terminal array 115, the seventh connection terminal array 116, the eighth connection terminal array 117, the ninth connection terminal array 118, and the tenth connection terminal array 119 may be respectively defined as the second connection terminal 1111, the third connection terminal 1121, the fourth connection terminal 1131, the fifth connection terminal 1141, the sixth connection terminal 1151, the seventh connection terminal 1161, the eighth connection terminal 1171, the ninth connection terminal 1181, and the tenth connection terminal 1191, respectively. In an embodiment, the first to tenth connection terminals 1101 to 1191 may be respectively connection terminals included in different connection terminal arrays and may be arranged in a straight line in the second direction (e.g., the Y direction). For example, the first to tenth connection terminals 1101 to 1191 may be aligned in a straight line in the second direction (e.g., the Y direction). However, embodiments of the present inventive concept are not necessarily limited thereto and the outermost connection terminal among the connection terminals may be defined in the +X direction in some embodiments.

According to an embodiment, the pair of window patterns 120a and 120b, which extend longitudinally in the first direction (e.g., the X direction) and are spaced apart from each other in the second direction (e.g., the Y direction), may be disposed in the target image TI where the backside surface 100a of the package substrate 100 is illustrated. A vent hole may be formed in a lower surface of the package substrate 100. The vent hole may provide a path through which air and an encapsulant of the encapsulation layer 300 configured to seal a semiconductor chip of a semiconductor package are discharged. As a result, the encapsulant may fill the vent hole and an inner portion of the semiconductor package with the semiconductor chip mounted thereon, and thus, the encapsulant exposed at the vent hole may form the window patterns 120a and 120b.

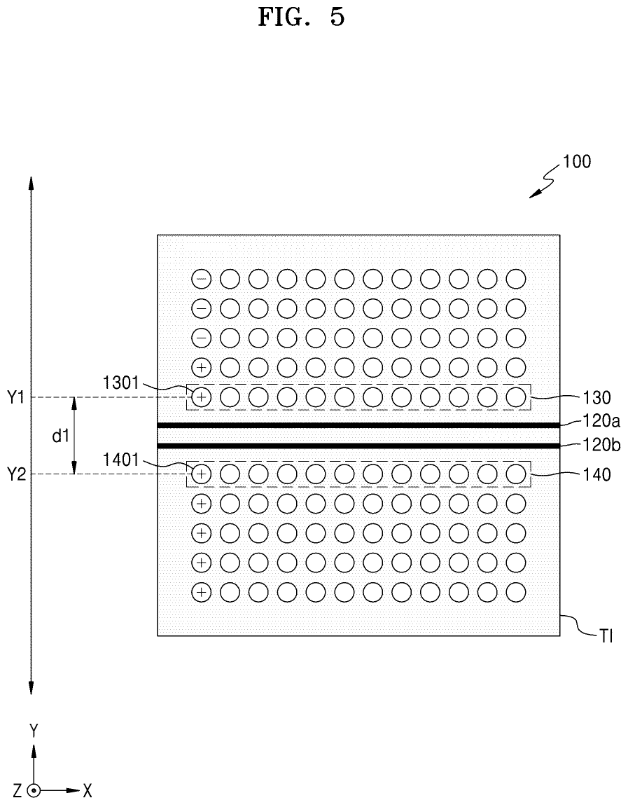

Referring to FIGS. 4 and 5 in conjunction with FIG. 2, operation S120 of measuring shift values of a pair of window patterns may include operation S122 of measuring position values of the plurality of connection terminal arrays 110 to 119 in the second direction (e.g., the Y direction) in the target image TI.

Positions of the plurality of connection terminal arrays 110 to 119 in the second direction (e.g., the Y direction) may be respectively defined as positions of the plurality of connection terminals 1101 to 1191, respectively disposed outermost (e.g., in the −X direction), in the second direction (the Y direction). According to an embodiment, the plurality of connection terminals 1101 to 1191 may have a circular shape with respect to a horizontal plane. Positions of the plurality of connection terminals 1101 to 1191 respectively disposed outermost in the second direction (e.g., in the Y direction) may each be defined as a position of the center point of a circular shape in the second direction (e.g., the Y direction).

A position of the first connection terminal array 110 in the second direction (e.g., the Y direction) may be defined as a position Y_a of the center point of the first connection terminal 1101 in the second direction (e.g., the Y direction). A position of the second connection terminal array 111 in the second direction (e.g., the Y direction) may be defined as a position Y_b of the center point of the second connection terminal 1111 in the second direction (e.g., the Y direction). A position of the third connection terminal array 112 in the second direction (e.g., the Y direction) may be defined as a position Y_c of the center point of the third connection terminal 1121 in the second direction (e.g., the Y direction). A position of the fourth connection terminal array 113 in the second direction (e.g., the Y direction) may be defined as a position Y_d of the center point of the fourth connection terminal 1131 in the second direction (e.g., the Y direction). A position of the fifth connection terminal array 114 in the second direction (e.g., the Y direction) may be defined as a position Y_e of the center point of the fifth connection terminal 1141 in the second direction (e.g., the Y direction).

In an embodiment, the sixth to tenth connection terminal arrays 115 to 119 may be arranged in a second region opposite (e.g., in the Y direction) to a first region where the first to fifth connection terminal arrays 110 to 114, with respect to a boundary line corresponding to the pair of window patterns 120a and 120b. A position of the sixth connection terminal array 115 in the second direction (e.g., the Y direction) may be defined as a position Y_f of the center point of the sixth connection terminal 1151 in the second direction (e.g., the Y direction). A position of the seventh connection terminal array 116 in the second direction (e.g., the Y direction) may be defined as a position Y_g of the center point of the seventh connection terminal 1161 in the second direction (e.g., the Y direction). A position of the eighth connection terminal array 117 in the second direction (e.g., the Y direction) may be defined as a position Y_h of the center point of the eighth connection terminal 1171 in the second direction (e.g., the Y direction). A position of the ninth connection terminal array 118 in the second direction (e.g., the Y direction) may be defined as a position Y_i of the center point of the ninth connection terminal 1181 in the second direction (e.g., the Y direction). A position of the tenth connection terminal array 119 in the second direction (e.g., the Y direction) may be defined as a position Y_h of the center point of the tenth connection terminal 1191 in the second direction (e.g., the Y direction).

Accordingly, in an embodiment, position values of the plurality of connection terminal arrays 110 to 119 in the second direction (e.g., the Y direction) may be measured by measuring positions of center points of the plurality of connection terminals 1101 to 1191 in the second direction (e.g., the Y direction). A position value of a first center connection terminal array 130 in the second direction (e.g., the Y direction) and a position value of a second center connection terminal array 140 in the second direction (e.g., the Y direction) may be measured along with position values of the other connection terminal arrays in the second direction (e.g., the Y direction).

Referring to FIGS. 4 and 5 in conjunction with FIG. 2, operation S120 of measuring the shift values of the pair of window patterns may include operation S123 of defining the first center connection terminal array 130 and the second center connection terminal array 140 having the largest difference value of position value differences between an adjacent plurality of connection terminal arrays in the second direction (e.g., the Y direction).

In an embodiment, after the position values of the plurality of connection terminal arrays 110 to 119 in the second direction (e.g., the Y direction) are measured, connection terminal arrays farthest away from each other among the plurality of connection terminal arrays 110 to 119 adjacent to one another may be respectively defined as the first center connection terminal array 130 and the second center connection terminal array 140. Therefore, the fifth connection terminal array 114 illustrated in FIG. 4 may be defined as the first center connection terminal array 130, and the sixth connection terminal array 115 may be defined as the second center connection terminal array 140. In an embodiment, the length of each of the pair of window patterns 120a and 120b in the first direction (e.g., the X direction) may be greater than the length of each of the first center connection terminal array 130 and the second center connection terminal array 140 in the first direction (e.g., in the X direction).

The first center connection terminal array 130 may be configured with a plurality of first center connection terminals 1301 which are arranged to be spaced apart from one another in the first direction (e.g., the X direction), and the second center connection terminal array 140 may be configured with a plurality of second center connection terminals 1401 which are arranged to be spaced apart from one another in the first direction (e.g., the X direction).

A position of the first center connection terminal array 130 in the second direction (e.g., the Y direction) may be defined as a position of the center point of the first center connection terminal 1301 in the second direction (e.g., the Y direction), and a position of the second center connection terminal array 140 in the second direction (e.g., the Y direction) may be defined as a position of the center point of the second center connection terminal 1401 in the second direction (e.g., the Y direction). As shown in FIG. 5, a position of the first center connection terminal array 130 in the second direction (e.g., the Y direction) may be a first point Y1, and a position of the second center connection terminal array 140 in the second direction (e.g., the Y direction) may be a second point Y2.

The difference (e.g., distance in the Y direction) between the first point Y1 and the second point Y2 may be a first distance d1. In this embodiment, the first distance d1 may be greater than a distance between the first center connection terminal array 130 and the fourth connection terminal array 113 in the second direction (e.g., the Y direction), or may be greater than a distance between the second center connection terminal array 140 and the seventh connection terminal array 116 in the second direction (e.g., the Y direction). Also, the first distance d1 may be greater than a distance between adjacent connection terminal arrays of the first to fourth connection terminal arrays 110 to 113, and may be greater than a distance between adjacent connection terminal arrays of the seventh to tenth connection terminal arrays 116 to 119.

According to an embodiment, the pair of window patterns 120a and 120b may be arranged between the first center connection terminal array 130 and the second center connection terminal array 140 (e.g., in the Y direction). In some embodiments, based on a product of a semiconductor package, the pair of window patterns 120a and 120b may be disposed closer to one of the first center connection terminal array 130 and the second center connection terminal array 140 (e.g. in the Y direction).

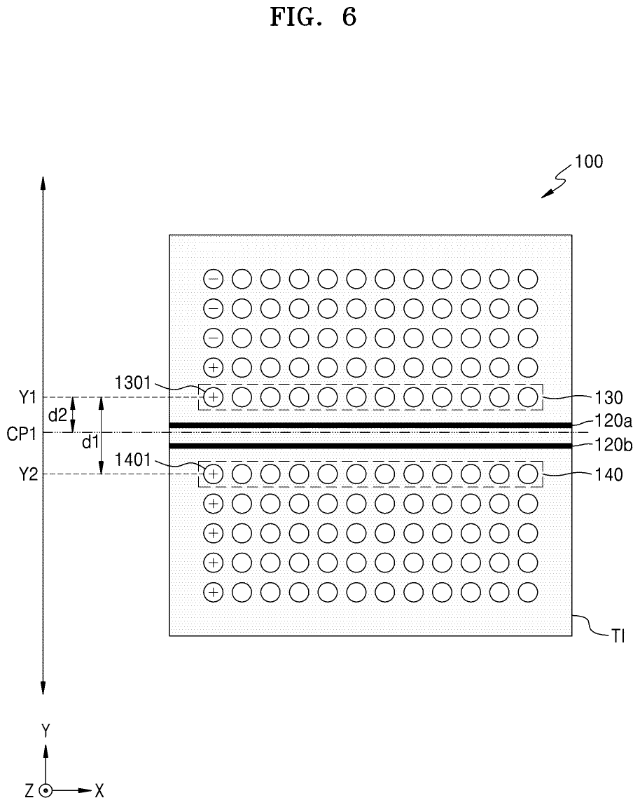

Referring to FIG. 6 in conjunction with FIG. 2, operation S120 of measuring the shift values of the pair of window patterns may include operation S124 of obtaining a first center position value CP1 (e.g. in the Y direction) between a position of the first center connection terminal array 130 in the second direction (e.g., the Y direction) and a position of the second center connection terminal array 140 in the second direction (the Y direction).

According to an embodiment, the first center position value CP1 may be calculated by calculating an average of the first point Y1 and the second point Y2. In an embodiment, a distance (e.g., in the Y direction) up to the first center connection terminal array 130 from a virtual axis having the first center position value CP1 in the first direction (e.g., the X direction) may be defined as a second distance d2, and the second distance d2 may be a half value of the first distance d1.

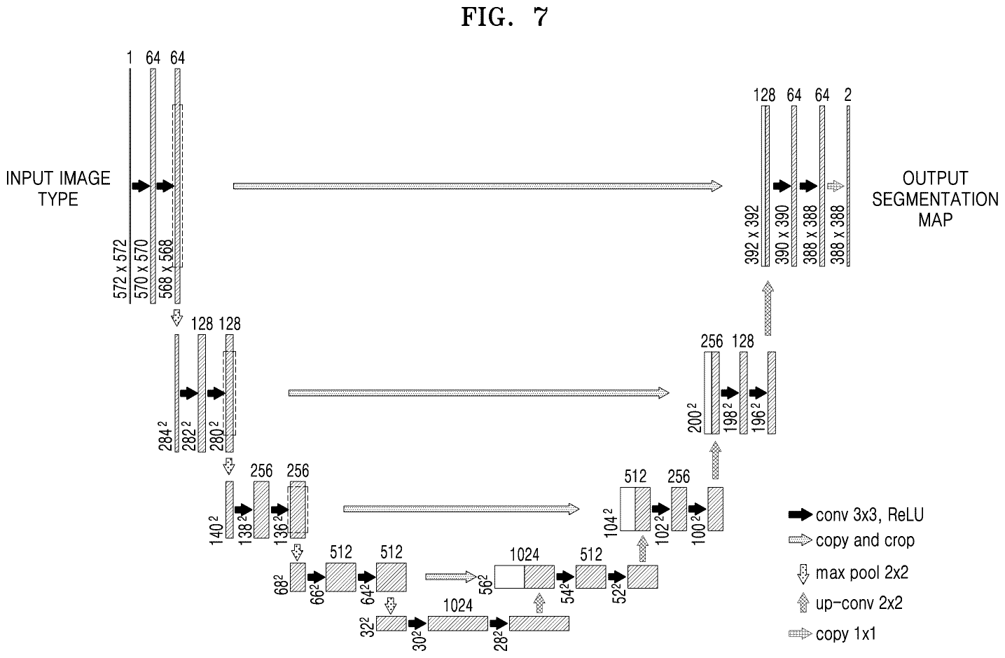

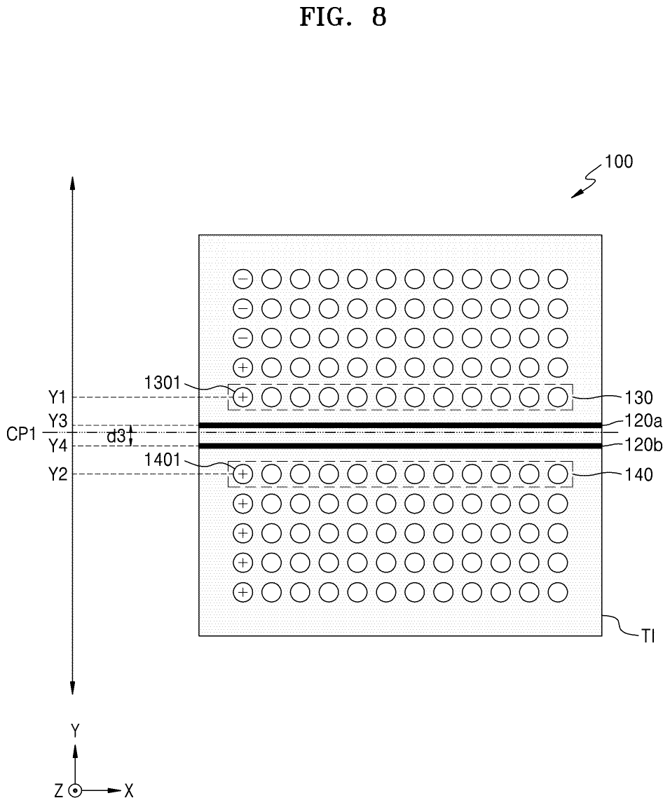

Referring to FIGS. 7 and 8 in conjunction with FIG. 2, operation S120 of measuring the shift values of the pair of window patterns may include operation S125 of measuring position values of the pair of window patterns 120a and 120b in the second direction (e.g., the Y direction) based on a U-Net model.

The U-Net model is described with reference to FIG. 7. In an embodiment, the U-Net model may be a representative segmentation technique, and segmentation may be a scheme which divides a region on a recognized object. In an embodiment, U-Net may segment, by tetragon units, input image data which is referred to as a patch and does not overlap, and a divided patch may undergo a contraction path and expansion path process, as illustrated in FIG. 7. In a contraction path, a feature map may be generated with a context through down-sampling, and in an expansion path, up-sampling may be again executed on a feature map. In each process of up-sampling, a feature map generated in the contraction path may be cut and connected with another, thereby preventing the loss of a contour line of an object. Since the final output result does not fill a space through padding, an empty space may occur because the final output result is less than an input path, and thus, the empty space may be filled through mirroring by using an overlap-tile technique, thereby enabling smooth segmentation.

For example, in an embodiment the pair of window patterns 120a and 120b differentiated from a background color of the package substrate 100 may be detected by segmenting the target image TI, based on the U-Net model. A first window pattern 120a and a second window pattern 120b each configuring the pair of window patterns 120a and 120b may be spaced apart from each other by a third distance d3 in the second direction (e.g., the Y direction).

A position of the first window pattern 120a in the second direction (e.g., the Y direction) may be recorded and stored as a third point Y3, and a position of the second window pattern 120b in the second direction (e.g., the Y direction) may be recorded and stored as a fourth point Y4.

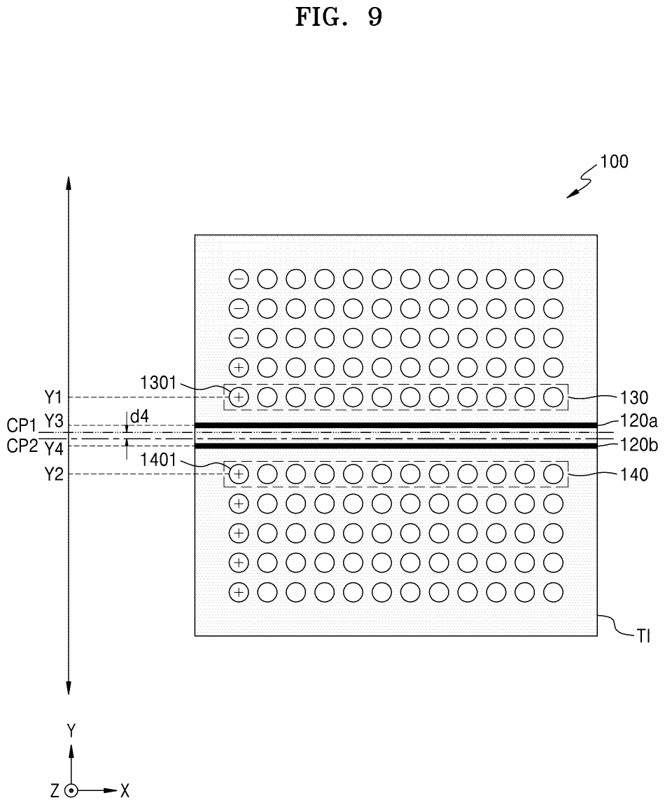

However, a method of measuring shift values of a pair of window patterns is not necessarily limited to the U-Net model. According to some embodiments, position values of the pair of window patterns 120a and 120b in the second direction (e.g., the Y direction) may be measured by using various segmentation techniques. For example, in some embodiments the position values of the pair of window patterns 120a and 120b in the second direction (e.g., the Y direction) may be measured by using a segmentation network structure such as U-net2+, U-net3+, Deeplab, or Mask R-CNN. However, embodiments of the present inventive concept are not necessarily limited thereto. Referring to FIG. 9 in conjunction with FIG. 2, operation S120 of measuring the shift values of the pair of window patterns may include operation S126 of obtaining a second center position value CP2 between positions of the pair of window patterns 120a and 120b in the second direction (e.g., the Y direction).

According to an embodiment, the second center position value CP2 may be calculated by calculating an average of the third point Y3 and the fourth point Y4 (e.g., in the Y direction). The second center position value CP2 may be a center value between the first window pattern 120a and the second window pattern 120b in the second direction (e.g., the Y direction).

Referring to FIG. 9 in conjunction with FIG. 2, operation S120 of measuring the shift values of the pair of window patterns may include operation S127 of defining the difference between the first center position value CP1 and the second center position value CP2 as a shift value.

According to an embodiment, the first center position value CP1 may be the center value between the first center connection terminal array 130 and the second center connection terminal array 140 (e.g., in the Y direction), and the second center position value CP2 may be the center value between the first window pattern 120a and the second window pattern 120b (e.g., in the Y direction). The first center position value CP1 may match the second center position value CP2. The first center position value CP1 matching the second center position value CP2 may denote that the plurality of connection terminal arrays 110 to 119 and the pair of window patterns 120a and 120b are formed to be symmetrical with respect to the center of the package substrate 100. The shift value being greater than 0 may denote that the plurality of connection terminal arrays 110 to 119 are staggered with respect to the center of the pair of window patterns 120a and 120b.

Referring to FIG. 9 in conjunction with FIG. 2, the method of detecting a defective semiconductor package, according to an embodiment, may include operation S130 of determining whether a semiconductor package is defective or is not defective, based on comparison between the shift value and a predetermined reference value.

As described above, in an embodiment the shift value being greater than 0 may denote that the plurality of connection terminal arrays 110 to 119 are staggered with respect to the center of the pair of window patterns 120a and 120b. When the shift value is excessive, the reliability of a semiconductor package may be weakened. According to an embodiment, a reference value (e.g., a predetermined reference value) which is allowable, may be in a range of about 200 μm to about 500 μm. However, the reference value may be changed based on the product of a semiconductor package.

In this case, the method of detecting a defective semiconductor package may include operation S131 of determining that the package substrate 100 is normal, when the shift value is less than or equal to the reference value. A case where the shift value is less than or equal to the reference value may denote that the plurality of connection terminal arrays 110 to 119 are attached adjacent to the center of the pair of window patterns 120a and 120b.

In an embodiment, the method of detecting a defective semiconductor package may include operation S132 of determining that the package substrate 100 is defective, when the shift value is greater than the reference value. A case where the shift value is greater than the reference value may denote that the plurality of connection terminal arrays 110 to 119 are more staggered than a threshold value with respect to the center of the pair of window patterns 120a and 120b. However, embodiments of the present disclosure are not necessarily limited thereto and in some embodiments, the package substrate 100 may be determined to be defective when the shift value is greater than or equal to the reference value.

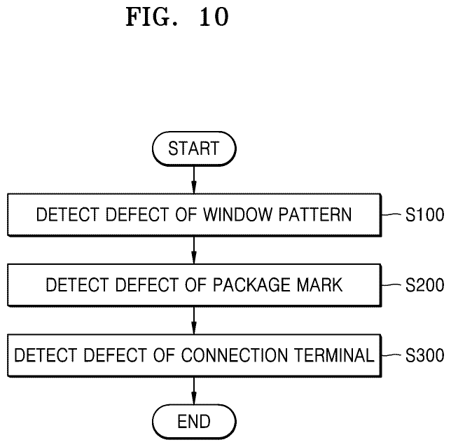

FIG. 10 is a flowchart of a method of detecting a defective semiconductor package, according to an embodiment and is a flowchart including a method of detecting a defective window pattern illustrated in FIG. 2.

Referring to FIG. 10, the method of detecting a defective semiconductor package, according to an embodiment, may include operation S200 of detecting whether a package mark 310 (see FIG. 1) formed on a front-side surface (e.g., a front-side surface 300a (see FIG. 1) of a molding layer 300 (see FIG. 1) of a semiconductor package 10 (see FIG. 1) is defective or is not defective, after operation S100 of detecting whether window patterns 120a and 120b (see FIG. 1) formed on a backside surface of a package substrate 100 (see FIG. 1) are defective or are not defective. The method of detecting a defective semiconductor package, according to an embodiment, may include operation S300 of detecting whether the plurality of connection terminals 1101 to 1191 configuring the plurality of connection terminal arrays 110 to 119 are defective or are not defective, after detecting whether the package mark 310 (see FIG. 1) of the semiconductor package 10 (see FIG. 1) is defective or is not defective. In an embodiment, operation S300 of detecting whether the plurality of connection terminals 1101 to 1191 are defective or are not defective may determine whether the plurality of connection terminals 1101 to 1191 are uniformly arranged in one direction without being staggered with one another.

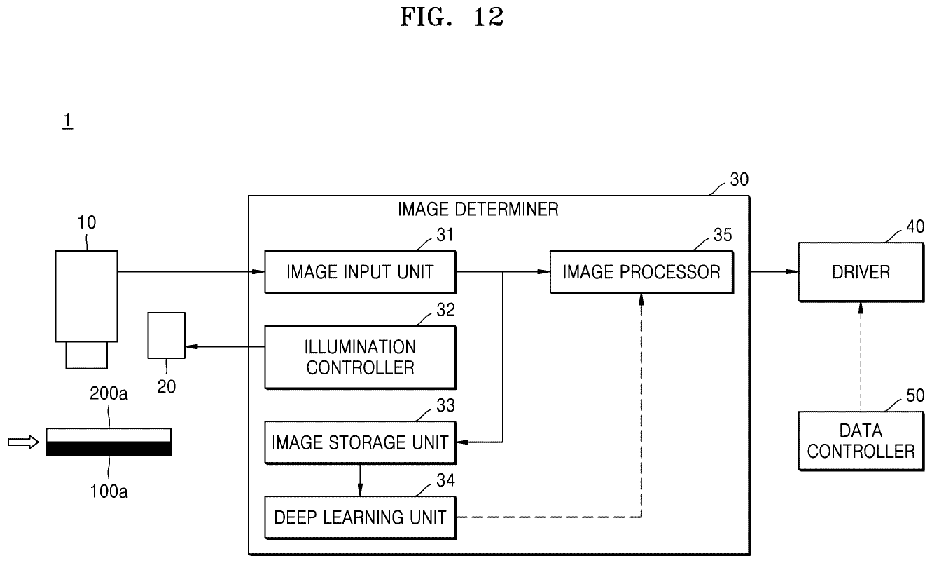

FIGS. 11 and 12 are configuration diagrams illustrating a defective semiconductor package detection system 1 for implementing a method of detecting a defective semiconductor package, according to an embodiment. Hereinafter, FIGS. 11 and 12 are described.

The defective semiconductor package detection system 1 according to an embodiment, as illustrated in FIG. 1, may include a camera 10 which photographs a backside surface 100a of a package substrate 100 (see FIG. 1) placed on a test table, an image determiner 30 which receives an image signal from the video camera 10 and determines whether the package substrate 100 is normal or not, an illumination device 20 which is installed for clarity of an image of a fine portion, a driver 40 which controls and drives a programmable logic controller (PLC) based on the determination result of the image determiner 30, and a data controller 50 which transfers a control signal to the driver 40 based on information received and accumulated from the image determiner 30. The image determiner 30 may also include an image processor 35.

In an embodiment, the camera 10 used to detect a defect of a semiconductor package according to an embodiment may be a differential interference contrast (DIC) camera having high resolution. In an embodiment, the DIC camera may apply a DIC filter, a polarization filter, and an analysis filter to a camera barrel to more sharply capture an image input from a lens. In an embodiment, the camera 10 may be a camera which captures a still image. However, embodiments of the present disclosure are not necessarily limited thereto and a line scan camera may be applied to photograph a panel while moving the test table at a certain speed. In an embodiment in which a line scan camera is used, image data may be provided by continuously photographing the backside surface 100a of the package substrate 100 (see FIG. 1), and thus, determination operations may be comprehensively processed, thereby simplifying an overall processing process. In an embodiment, the illumination device 20 may be configured with a light-emitting diode (LED), and irradiated light may have a wavelength in a range of about 400 nm to about 500 nm. Based on such an illumination unit, the camera 10 may more sharply capture an image of the backside surface 100a of the package substrate 100 (see FIG. 1). However, embodiments of the present inventive concept are not necessarily limited thereto and the illumination device 20 may vary.

In an embodiment, the image determiner 30 may include an image input unit 31 which receives an image from the camera 10, an illumination controller 32 which is connected to the illumination 20 to control and transmit a driving control signal for the illumination 20, an image storage unit 33 which stores an image input from the camera 10 to the image input unit 31, and a deep learning unit 34 which is configured to detect a position of a window pattern in an image received from the image input unit 31, based on a deep learning model (e.g., the U-Net model).

The data controller 50 may be configured to transfer a control signal to the driver 40 based on information received and accumulated from the image determiner 30. In an embodiment, the data controller 50 may be, for example, a machine analysis and re-engineering system (MARS).

According to an embodiment, after determining whether the window patterns 120a and 120b formed on the backside surface 100a of the package substrate 100 (see FIG. 1) are defective or not, as illustrated in FIG. 12, whether the semiconductor mark 310 formed on the front-side surface 300a of the encapsulation layer 300 (see FIG. 1) is defective or is not defective may be detected by turning over the semiconductor package 11.

Hereinabove, non-limiting embodiments of the present inventive concept have been described in the drawings and the specification. Embodiments have been described by using the terms set forth herein, but this has been merely used for describing embodiments of the present inventive concept and has not been used for limiting a meaning or limiting the scope of the present inventive concept. Therefore, it may be understood by those of ordinary skill in the art that various modifications and other equivalent embodiments may be implemented from the described embodiments of the present inventive concept.

While the present inventive concept has been particularly shown and described with reference to embodiments thereof, it will be understood that various changes in form and details may be made therein without departing from the spirit and scope of the present inventive concept.

What is claimed is:

1. A method of detecting a defective semiconductor package, the method comprising:
obtaining a target image of a backside surface of a package substrate that includes a pair of window patterns and a plurality of connection terminal arrays extending in a first direction;
measuring a shift value of the pair of window patterns illustrated in the target image; and
comparing the shift value with a reference value to determine whether the package substrate is defective or is not defective,
wherein the measuring of the shift value of the pair of window patterns comprises:
obtaining a first center position value between a pair of adjacent connection terminal arrays that are farthest away from each other among pairs of adjacent connection terminal arrays of the plurality of connection terminal arrays;
obtaining a second center position value between the pair of window patterns; and
defining a difference between the first center position value and the second center position value as the shift value.

2. The method of claim 1, wherein, in the obtaining of the first center position value, the first center position value is an average of position values of the pair of adjacent connection terminal arrays in a second direction perpendicular to the first direction.

3. The method of claim 2, wherein each of the pair of adjacent connection terminal arrays comprises a solder ball having a circular shape in a horizontal plane.

4. The method of claim 1, wherein the determining of whether the package substrate is defective or is not defective comprises:
when the shift value is greater than the reference value, determining that the package substrate is defective; and
when the shift value is less than or equal to the reference value, determining that the package substrate is not defective.

5. The method of claim 1, wherein the obtaining of the second center position value comprises obtaining positions of the pair of window patterns based on a U-Net model.

6. The method of claim 1, wherein a length of the pair of window patterns in the first direction is greater than a length of the pair of adjacent connection terminal arrays in the first direction.

7. The method of claim 1, wherein the pair of window patterns comprises a pattern of a molding layer exposed at the backside surface of the package substrate.

8. The method of claim 1, wherein, in the obtaining of the second center position value, the pair of window patterns is disposed between the pair of adjacent connection terminal arrays in a second direction perpendicular to the first direction.

9. The method of claim 1, further comprising, after the determining of whether the package substrate is defective or is not defective, detecting a defect of a package mark formed on a front-side surface of the package substrate.

10. The method of claim 1, wherein the reference value is in a range of about 200 μm to about 500 μm.

11. A method of detecting a defective semiconductor package, the method comprising:
obtaining a target image of a backside surface of a package substrate that includes a pair of window patterns and a plurality of connection terminal arrays extending in a first direction;
measuring a position value of each of the plurality of connection terminal arrays in a second direction perpendicular to the first direction in the target image;
defining a first center connection terminal array and a second center connection terminal array that comprise a pair of adjacent connection terminal arrays that are farthest away from each other among pairs of adjacent connection terminal arrays of the plurality of connection terminal arrays;
obtaining a first center position value between a position value of the first center connection terminal array in the second direction and a position value of the second center connection terminal array in the second direction;
measuring position values of each of the pair of window patterns in the second direction;
obtaining a second center position value between the position values of the pair of window patterns in the second direction;
defining a difference between the first center position value and the second center position value as a shift value; and
comparing the shift value with a reference value to determine whether the package substrate is defective or is not defective.

12. The method of claim 11, wherein, in the obtaining of the target image, the target image is an image obtained by extracting an image captured by a camera of the backside surface of the package substrate.

13. The method of claim 11, wherein the determining of whether the package substrate is defective or is not defective comprises:
when the shift value is greater than the reference value, determining that the package substrate is defective; and
when the shift value is less than or equal to the reference value, determining that the package substrate is not defective.

14. The method of claim 11, wherein, in the measuring of the position value of each of the plurality of connection terminal arrays in the second direction in the target image, the position value of each of the plurality of connection terminal arrays is a position value of a center point of a connection terminal having a circular shape and configuring each of the plurality of connection terminal arrays, with respect to a horizontal plane.

15. The method of claim 11, wherein the obtaining of the position value of each of the pair of window patterns in the second direction comprises obtaining the position value of each of the pair of window patterns in the second direction based on a U-Net model.

16. The method of claim 11, wherein the pair of window patterns comprises a pattern of a molding layer exposed at the backside surface of the package substrate.

17. The method of claim 11, further comprising, after the comparing of the shift value with a reference value to determine whether the package substrate is defective or is not defective, turning over the package substrate and inspecting a mark formed on a front-side surface of the package substrate that is opposite to the backside surface of the package substrate.

18. The method of claim 17, wherein the package substrate is a printed circuit board (PCB).

19. A method of detecting a defective semiconductor package, the method comprising:
obtaining an image of a backside surface of a printed circuit board (PCB) that includes a pair of window patterns and a plurality of solder ball arrays extending in an X-axis direction;
extracting a target image from the image;
measuring a position value of each of the plurality of solder ball arrays in a Y-axis direction in the target image;
defining a first solder ball array and a second solder ball array that comprise a pair of adjacent solder ball arrays that are farthest away from each other in the Y-axis direction among pairs of adjacent solder ball arrays of the plurality of solder ball arrays;
obtaining a first center position value that is an average of a position value of the first solder ball array in the Y-axis direction and a position value of the second solder ball array in the Y-axis direction;
measuring a position value of each of the pair of window patterns in the Y-axis direction;
obtaining a second center position value that is an average of the position values of the pair of window patterns in the Y-axis direction;
defining a difference between the first center position value and the second center position value as a shift value; and
comparing the shift value with a reference value to determine whether the PCB is defective or is not defective.

20. The method of claim 19, wherein the determining of whether the PCB is defective or is not defective comprises:
when the shift value is greater than the reference value, determining that the PCB is defective; and
when the shift value is less than the reference value, determining that the PCB is not defective.
